(19) United States
(12) Patent Application Publication
(10) Pub. No.: US 2015/0064929 A1
(43) Pub. Date: Mar. 5, 2015

(54) METHOD OF GAP FILLING

(71) Applicant: UNITED MICROELECTRONICS CORP., Hsin-Chu City (TW)

(72) Inventors: I-Ming Tseng, Kaohsiung City (TW); Shih-Hung Tsai, Tainan City (TW); Rai-Min Huang, Taipei City (TW); Yu-Ting Lin, Nantou County (TW); Chien-Ting Lin, Hsinchu City (TW); Shih-Fang Tzou, Tainan City (TW)

(73) Assignee: UNITED MICROELECTRONICS CORP., Hsin-Chu City (TW)

(21) Appl. No.: 14/018,447

(22) Filed: Sep. 5, 2013

(51) Int. Cl. H01L 21/02

(52) U.S. Cl. CPC H01L 21/022; H01L 21/02112; H01L 21/02233
USPC 438/762

(57) ABSTRACT

A method of gap filling includes providing a substrate having a plurality of gaps formed therein. Then, an in-situ steam generation oxidation is performed to form an oxide liner on the substrate. The oxide liner is formed to cover surfaces of the gaps. Subsequently, a high aspect ratio process is performed to form an oxide protecting layer on the oxide liner. After forming the oxide protecting layer, a flowable chemical vapor deposition is performed to form an oxide filling on the oxide protecting layer. More important, the gaps are filled up with the oxide filling layer.

### BACKGROUND OF THE INVENTION

1. Field of the Invention

The present invention relates to a semiconductor manufacturing method, and more particularly, to a semiconductor manufacturing method of gap filling.

2. Description of the Prior Art

In order to provide integrated circuit (ICs) with increased performance, characteristic dimensions of devices and spacings on ICs, that are sizes of semiconductor device geometries, have been dramatically decreased.

As the dimension of device shrinks, the aspect ratio of the gap formed in semiconductor patterns is increased. Consequently, it is getting more and more difficult to fill the gap with a higher aspect ratio. In view of the above, there exists a need to provide a high quality and interstice-free material for filling up the gaps formed in the semiconductor patterns.

### SUMMARY OF THE INVENTION

According to an aspect of the present invention, a method of gap filling is provided. According to the provided method of gap filling, a substrate having a plurality of gaps formed therein is provided. An in-situ steam generation (hereinafter abbreviated as ISSG) oxidation is performed to form an oxide liner on the substrate. The oxide liner is formed to cover surfaces of the gaps. Subsequently, a high aspect ratio process (hereinafter abbreviated as HARP) is performed to form an oxide protecting layer on the oxide liner. After forming the oxide protecting layer, a flowable chemical vapor deposition (hereinafter abbreviated as FCVD) is performed to form an oxide filling layer on the oxide protecting layer. More important, the gaps are filled up with the oxide filling layer.

According to another aspect of the present invention, a method of gap filling is provided. According to the provided method of gap filling, a substrate having a plurality of gaps formed therein is provided. A first oxide layer covering surfaces of the gaps is subsequently formed on the substrate. Next, a second oxide layer is formed on the first oxide layer and an amorphous silicon layer is formed on the second oxide layer. An oxide filling layer is then formed on the amorphous silicon layer. More important, the gaps are filled up with the oxide filling layer.

According to the method gap filling provided by the present application, the second oxide layer formed by performing the HARP is provided on the first oxide layer formed by performing ISSG oxidation. The second oxide layer serves as a protecting layer during following processes such as FCVD or densification and thus silicon consumption is avoided.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIGS. 1-4 are schematic drawings illustrating a method of gap filling provided by a first preferred embodiment of the present invention, wherein

FIG. 2 is a schematic drawing in a step subsequent to FIG. 1,

FIG. 3 is a schematic drawing in a step subsequent to FIG. 2, and

FIG. 4 is a schematic drawing in a step subsequent to FIG. 3.

FIGS. 5-10 are schematic drawings illustrating a method of gap filling provided by a second preferred embodiment of the present invention, wherein

FIG. 6 is a schematic drawing in a step subsequent to FIG. 5,

FIG. 7 is a schematic drawing in a step subsequent to FIG. 6,

FIG. 8 is a schematic drawing in a step subsequent to FIG. 7,

FIG. 9 is a schematic drawing in a step subsequent to FIGS. 8, and

FIG. 10 is a schematic drawing in a step subsequent to FIG. 9.

### DETAILED DESCRIPTION

Please refer to FIGS. 1-4, which are schematic drawings illustrating a method of gap filling provided by a first preferred embodiment of the present invention. As shown in FIG. 1, a substrate 100 is provided. The substrate 100 can include a silicon-on-insulator (SOI) substrate or a bulk silicon substrate. A patterned hard mask 102 for defining placement of a plurality of gaps is formed on the substrate 100. In the preferred embodiment, the pattered hard mask layer 102 can be a multi-layered structure such as an oxide/nitride/oxide layer, but not limited to this. Subsequently, an etching process is performed to etch the substrate 100 through the patterned hard mask 102 and thus a plurality of gaps 104 are formed in the substrate 100. The gaps 104 can be shallow trenches in which insulating material is formed and thus shallow trench isolations (STIs) are obtained. The gaps 104 also can be formed to define fins required in non-planar transistor technology such as Fin Field effect transistor (FinFET) technology. Since those approaches are well-known to those skilled in the art, the details are omitted herein in the interest of brevity.

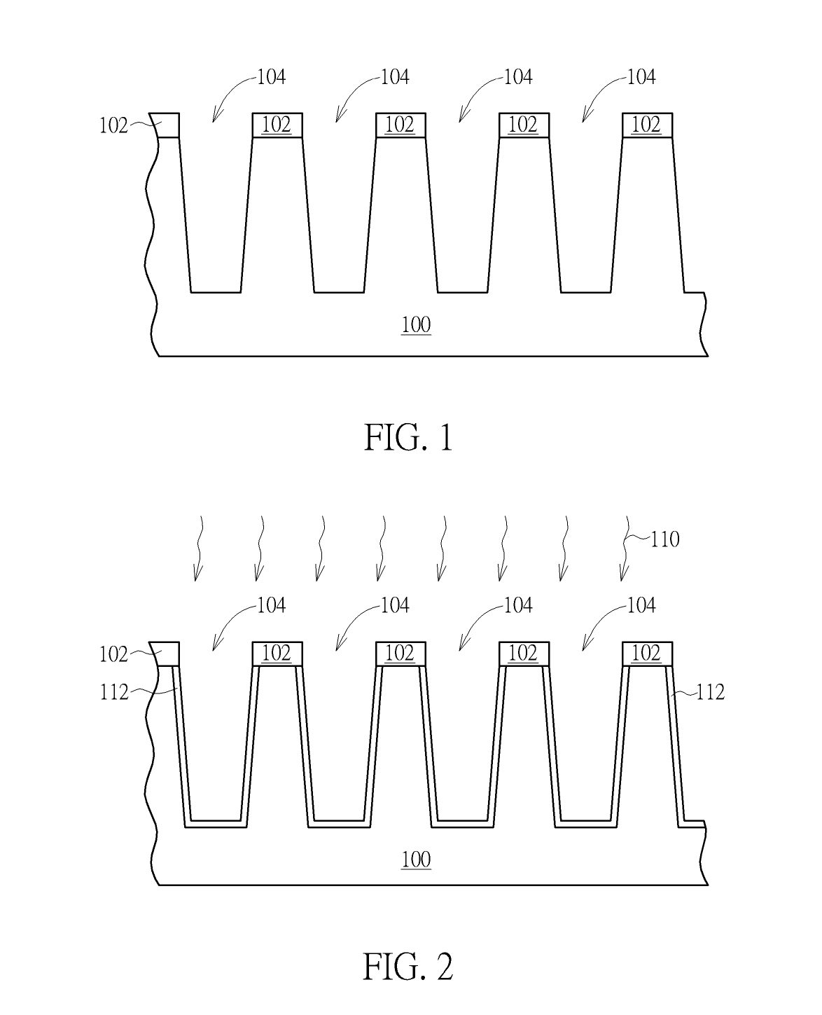

Please refer to FIG. 2. An in-situ steam generation (ISSG) oxidation 110 is performed to form a first oxide layer serving as an oxide liner 112 on the substrate 100. As shown in FIG. 2, the oxide liner 112 covers surfaces of the gaps 104. In one embodiment, the ISSG oxidation 110 can be carried out, for example but not limited to, in a rapid thermal process (RTP) apparatus, and the RTP apparatus may be any such apparatus known in the art. A thickness of the oxide liner 112 is between 15 Angstroms (Å) and 27 Å. It is noteworthy that because the oxide liner 112 is formed by oxidizing silicon material exposed in the gaps 104 with the ISSG oxidation 110, the thickness of the oxide liner 112 is limited, otherwise the dimension of the gaps 104 may be changed and unwanted variation to the manufacturing process is caused.

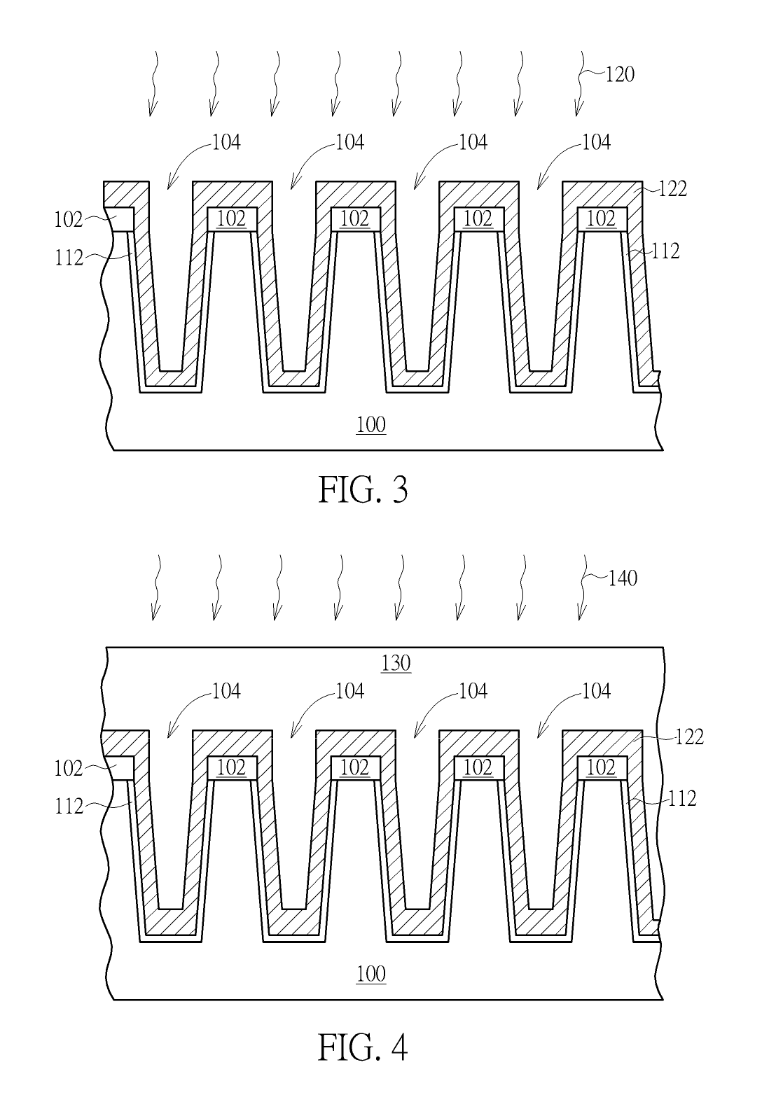

Please refer to FIG. 3. After forming the oxide liner 112, a high aspect ratio process (HARP) 120 is performed to form a second oxide layer serving as an oxide protecting layer 122 on the oxide liner 112. As shown in FIG. 3, the oxide protecting layer 122 covers both of the patterned hard mask 102 and the oxide liner 112. A thickness of the oxide protecting layer 122 is between 70 Å and 100 Å. In the preferred embodiment, the thickness of the oxide protecting layer 122 is preferably 100 Å. It is realized that when the aspect ratio of gaps/trenches is greater than about 7.0, voids are easily formed and embedded in the materials used to fill up the gaps/trenches. And HARP is thus developed as a particular CVD technology that meets the stringent gap filling requirement of 65 nm and below, and high aspect ratio greater than 7.0. Therefore, the oxide protecting layer 122 is formed by performing HARP 120, otherwise the bottom of the gaps 104 may not be covered and protected.

Please refer to FIG. 4. Next, a flowable chemical vapor deposition (FCVD) is performed to form an oxide filling layer 130 on the oxide protecting layer 122. As shown in FIG. 4, the gaps 104 are filled up with the oxide filling layer 130. Furthermore, it is observed that the oxide filling layer 130 formed by the FCVD is suitable to fill the gaps/trenches of high aspect ratio without any void or seam formed therein. However, the oxide filling layer 130 is not strong enough to sustain ensuing manufacturing processes. Therefore, a densification process 140 is performed to densify and strengthen the oxide filling layer 130. The densification process 140 includes, for example but not limited to, a steam thermal.

More important, the densification process 140 is often performed in a high temperature anneal in an oxygen-containing environment. Oxygen may get into the oxide filling layer 130, even into layers underneath the oxide filling layer 130 and thus silicon consumption is caused. It is found that the thin oxide liner 112 is not sufficient to prevent the silicon consumption. However, the oxide protecting layer 122 formed between the oxide filling layer 130 and the oxide liner 112 provides sustainable and sufficient prevention to silicon consumption. Therefore, the dimension of the gaps 104 is impervious to the following manufacturing processes.

After the densification process 140, required processes such as planarization or etching back process are performed. The details are well-known to those skilled in the art, and therefore are omitted for simplicity.

According to the method of gap filling provided by the first preferred embodiment, the second oxide layer 122 formed by performing the HARP 120 is provided on the patterned hard mask 102 and the first oxide layer 112 formed by performing ISSG oxidation 110. The second oxide layer 122 serves as a protecting layer in following processes such as FCVD or densification process 140 and thus silicon consumption is avoided. Accordingly, the method of gap filling is provided to fill up the gaps 104 with the insulating material without any void or seam formed therein. Furthermore, the method of gap filling provides solid and strong insulating material, which is sustainable to ensuing manufacturing processes, without causing any adverse variation to the dimensions.

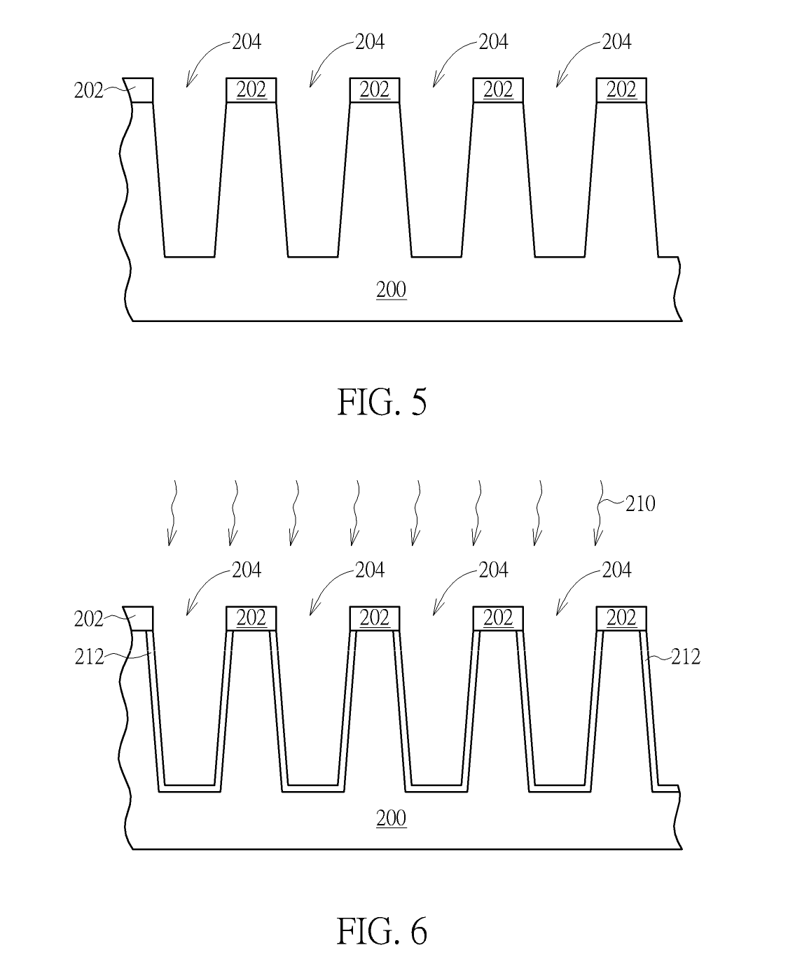

Please refer to FIGS. 5-10, which are schematic drawings illustrating a method of gap filling provided by a second preferred embodiment of the present invention. It should be understood that elements the same in both first and second preferred embodiments include the same material and thus those details are omitted in the interest of brevity. As shown in FIG. 5, a substrate 200 is provided. A patterned hard mask 202 for defining placement of a plurality of gaps is formed on the substrate. Subsequently, an etching process is performed to etch the substrate 200 through the patterned hard mask 202 and thus a plurality of gaps 204 are formed in the substrate 200. As mentioned above, the gaps 204 can be shallow trenches in which insulating material is formed and thus STIs are obtained. The gaps 204 also can be formed to define fins required in non-planar transistor technology such as FinFET technology. Since those approaches are well-known to those skilled in the art, the details are omitted herein in the interest of brevity.

Please refer to FIG. 6. An ISSG oxidation 210 is then performed to form a first oxide layer serving as an oxide liner 212 on the substrate 200. As shown in FIG. 6, the oxide liner 212 covers surfaces of the gaps 204. In one embodiment, the ISSG oxidation 210 can be carried out, for example but not limited to, in a RTP apparatus, and the RTP apparatus may be any such apparatus known in the art. A thickness of the oxide liner 212 is between 15 Å and 27 Å. It is noteworthy that because the oxide liner 212 is formed by oxidizing silicon material exposed in the gaps 204 with the ISSG oxidation 210, the thickness of the oxide liner 212 is limited, otherwise the dimension of the gaps 204 may be changed and unwanted variation to the manufacturing process is caused.

Please refer to FIG. 7. After forming the oxide liner 212, a HARP 220 is performed to form a second oxide layer serving as an oxide protecting layer 222 on the oxide liner 212. As shown in FIG. 7, the oxide protecting layer 222 covers both of the patterned hard mask 202 and the oxide liner 212. A thickness of the oxide protecting layer 222 is between 70 Å and 100 Å. In the preferred embodiment, the thickness of the oxide protecting layer 222 is preferably 70 Å. It is realized that when the aspect ratio of gaps/trenches is greater than about 7.0, voids are easily formed and embedded in the materials used to fill up the gaps/trenches. And HARP is thus developed as a particular CVD technology that meets the stringent gap filling requirement of 65 nm and below, and high aspect ratio greater than 7.0.

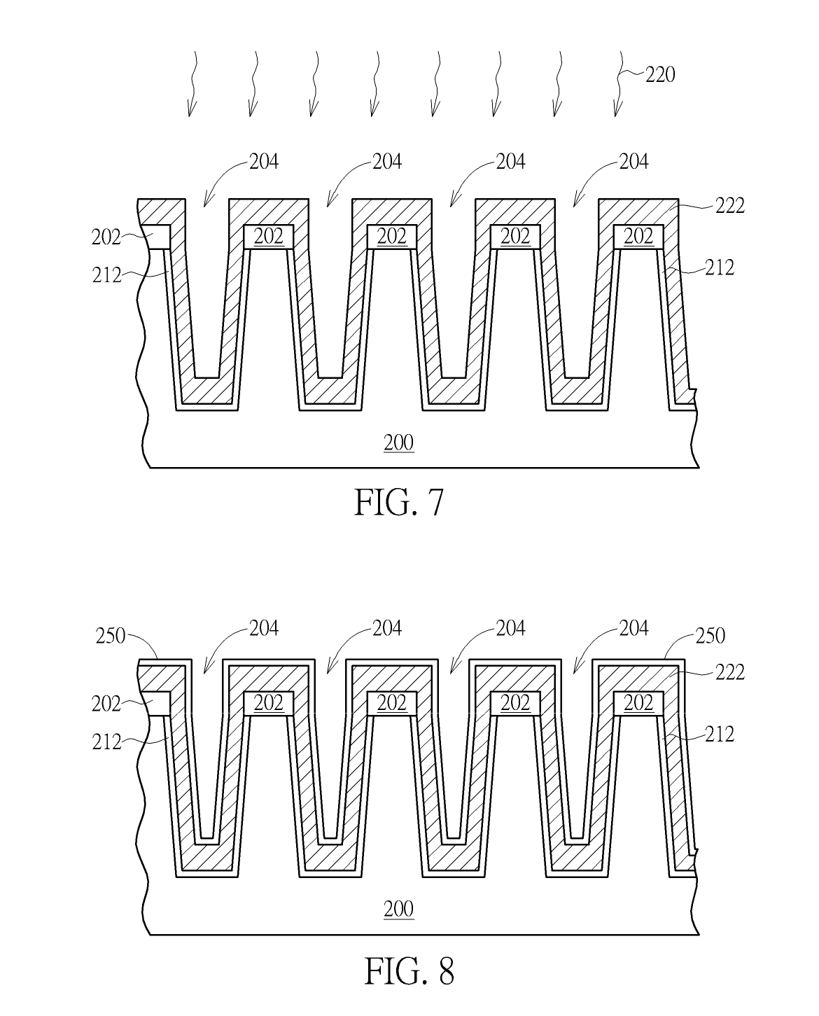

Please refer to FIG. 8. After forming the oxide protecting layer 222, an amorphous silicon layer 250 is formed on the oxide protecting layer 222. A thickness of the amorphous silicon layer 250 is between 30 Åand 50 Å.

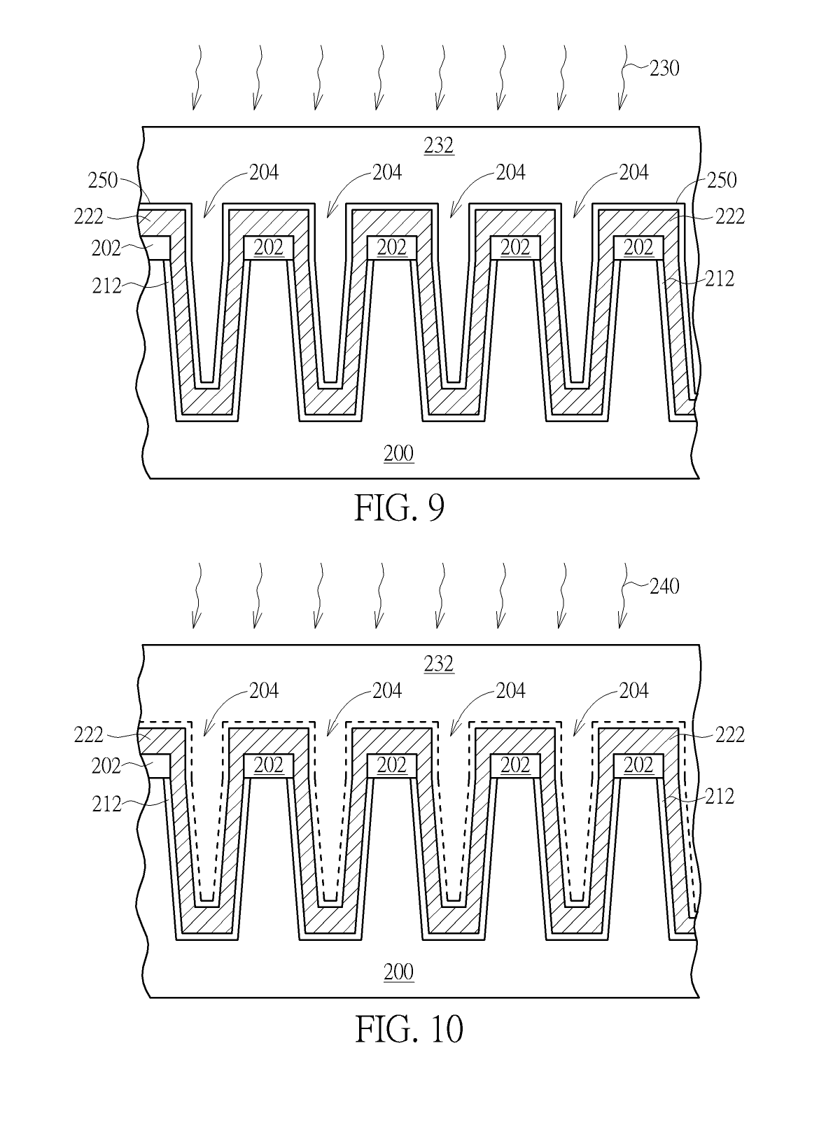

Please refer to FIGS. 9 and 10. Next, a FCVD 230 is performed to form an oxide filling layer 232 on the amorphous silicon layer 250. As shown in FIG. 9, the gaps 204 are filled up with the oxide filling layer 232. Furthermore, it is observed that the oxide filling layer 232 formed by the FCVD 230 is suitable to fill the gaps/trenches of high aspect ratio without any void or seam formed therein. However, the oxide filling layer 232 is not strong enough to sustain ensuing manufacturing processes. Therefore a densification process 240 is performed to densify and strengthen the oxide filling layer 232 as shown in FIG. 10. The densification process 240 includes, for example but not limited to, a steam thermal. As mentioned above, the densification process 240 is often performed in a high temperature anneal in an oxygen-containing environment. Oxygen may get into the oxide filling layer 232, even into layers underneath the oxide filling layer 232. In this preferred embodiment, the amorphous silicon layer 250 under the oxide filling layer 232 is able to provide silicon as a material attending the reaction. Therefore the entire amorphous silicon layer 250 is consumed in the densification process 240 as depicted by the dotted line in FIG. 10. Consequently, final result of the densification process 240 is improved because more silicon is provided by the amorphous silicon layer 250.

More important, when the amorphous silicon layer 250 is entirely consumed in the densification process 240, oxygen continues getting into the layer underneath. It is found that the thin oxide liner 212 is not sufficient to prevent the silicon consumption. However, the oxide protecting layer 222 formed between the oxide filling layer 232/amorphous silicon layer 250 and the oxide liner 212 provides sustainable and sufficient prevention to silicon consumption. Therefore, the dimension of the gaps 204 is impervious to the following manufacturing processes.

After the densification process 240, required processes such as planarization or etching back process are performed. The details are well-known to those skilled in the art, and therefore are omitted for simplicity.

According to the method of gap filling provided by the second preferred embodiment, the second oxide layer 222 formed by performing the HARP 220 is provided on the patterned hard mask 202 and the first oxide layer 212 formed by performing ISSG oxidation 210. The second oxide layer 222 serves as a protecting layer during following processes such as FCVD 230 or densification process 240 and thus silicon consumption is avoided. Accordingly, the method of gap filling is provided to fill up the gaps 204 with the insulating material without any void or seam formed therein. Furthermore, the method of gap filling provides solid and strong insulating material, which is sustainable to ensuing manufacturing processes, without causing any adverse variation to the dimensions.

According to the method gap filling provided by the present application, a second oxide layer formed by performing the HARP is provided between the ISSG oxide liner and the oxide filling layer, or between the ISSG oxide liner and the amorphous silicon layer. The second oxide layer therefore serves as a protecting layer in following processes such as FCVD or densification process and thus silicon consumption is avoided.

Those skilled in the art will readily observe that numerous modifications and alterations of the device and method may be made while retaining the teachings of the invention. Accordingly, the above disclosure should be construed as limited only by the metes and bounds of the appended claims.

1. A method of gap filling, comprising:
providing a substrate having a plurality of gaps formed therein, the gaps being defined by a patterned hard mask;
performing an in-situ steam generation (ISSG) oxidation to form an oxide liner on the substrate, the oxide liner covering surfaces of the gaps;
performing a high aspect ratio process (HARP) to form an oxide protecting layer on the oxide liner, and the oxide protecting layer covering the patterned hard mask and the oxide liner; and
performing a flowable chemical vapor deposition (FCVD) to form an oxide filling layer on the oxide protecting layer, and the gaps being filled up with the oxide filling layer.

2. The method of gap filling according to claim 1, wherein a thickness of the oxide liner is between 15 Angstroms (Å) and 27 Å.

3. The method of gap filling according to claim 1, wherein a thickness of the oxide protecting layer is between 70 Å and 100 Å.

4. The method of gap filling according to claim 3, wherein the thickness of the oxide protecting layer is preferably 100 Å.

5-6. (canceled)

7. The method of gap filling according to claim 1, further comprising forming an amorphous silicon layer on the oxide protecting layer before performing the FCVD.

8. The method of gap filling according to claim 7, where in wherein a thickness of the amorphous silicon layer is between 30 Åand 50 Å.

9. The method of gap filling according to claim 1, further comprising performing a densification process after forming the oxide filling layer.

10. The method of gap filling according to claim 9, wherein the densification process comprises steam thermal.

11. A method of gap filling, comprising:
providing a substrate having a plurality of gaps formed therein;
forming a first oxide layer on the substrate, the first oxide layer covering surfaces of the gaps;
forming a second oxide layer on the first oxide layer;
forming an amorphous silicon layer on the second oxide layer; and
forming an oxide filling layer on the amorphous silicon layer, and the gaps being filled up with the oxide filling layer.

12. The method of gap filling according to claim 11, wherein the first oxide layer is formed by performing an in-situ steam generation oxidation.

13. The method of gap filling according to claim 11, wherein a thickness of the first oxide layer is between 15 Å and 27 Å.

14. The method of gap filling according to claim 11, wherein the second oxide layer is formed by performing a high aspect ratio process.

15. The method of gap filling according to claim 11, wherein a thickness of the second oxide layer is between 70 Å and 100 Å.

16. The method of gap filling according to claim 15, wherein the thickness of the second oxide layer is preferably 70 Å.

17. The method of gap filling according to claim 11, wherein the gaps are defined by a patterned hard mask, and the second oxide layer covers the patterned hard mask and the first oxide layer.

18. The method of gap filling according to claim 11, wherein a thickness of the amorphous silicon layer is between 30 Å and 50 Å.

19. The method of gap filling according to claim 11, further comprising performing a densification process after forming the oxide filling layer.

20. The method of gap filling according to claim 19, wherein the densification process comprises steam thermal.
